(19) United States
(12) Patent Application Publication
(10) Pub. No.: US 2025/0122409 A1
(43) Pub. Date: Apr. 17, 2025

(54) PROTECTIVE MASKING TAPE FOR CIRCUIT BOARD TABS

(71) Applicant: Dell Products L.P., Round Rock, TX (US)

(72) Inventors: Wallace H. ABLES, Georgetown, TX (US); Steven R. ETHRIDGE, Austin, TX (US); James L. PETIVAN, Austin, TX (US); Earl BOONE, Round Rock, TX (US)

(73) Assignee: Dell Products L.P., Round Rock, TX (US)

(21) Appl. No.: 18/485,759

(22) Filed: Oct. 12, 2023

(51) Int. Cl. C09J 7/30; C09J 179/08; H05K 1/11

(52) U.S. Cl. CPC C09J 7/30; C09J 179/08; C09J 2203/326; C09J 2301/208; H05K 1/111; H05K 1/115

(57) ABSTRACT

An adhesive tape may include a first adhesive strip having an adhesive material applied to the first adhesive strip on a first side of the adhesive tape, a second adhesive strip having the adhesive material applied to the second adhesive strip on the first side of the adhesive tape, the second adhesive strip substantially parallel with the first adhesive strip and separated from the first adhesive strip by a distance, and a non-adhesive region between the first adhesive strip and the second adhesive strip wherein the non-adhesive region is substantially free of adhesive on the first side of the adhesive tape.

### TECHNICAL FIELD

The present disclosure relates in general to information handling systems, and more particularly to a protective masking tape adapted for masking circuit board tabs.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems may often use one or more circuit boards. A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board. To enable connectivity to other electrical and electronic components, circuit boards may include edge connectors at the edges thereof, wherein an edge connector may be configured to mate with a corresponding receptacle connector. Such edge connectors may comprise a plurality of parallel electrically-conductive tabs, such tabs often formed from an electrically-conductive metal plated with gold. Such tabs are also referred to as stubs, fingers, gold tabs, gold stubs, and gold fingers.

During the circuit board manufacturing process, and in particular during soldering reflow, wave solder, and rework steps during such process, masking tapes are often used to protect surfaces of tabs from flux and solder contamination. However, existing masking tapes for circuit board tabs have a fully-adhesive surface on the back side of the masking tape which may adhere to the surface of the tabs when applied. Accordingly, when the masking tape is removed from the tabs when circuit board assembly is complete, adhesive residue may be left on the tabs, thus contaminating the tabs.

### SUMMARY

In accordance with the teachings of the present disclosure, the disadvantages and problems associated with current approaches to masking circuit board tabs during assembly of a circuit board may be substantially reduced or eliminated.

In accordance with embodiments of the present disclosure, an adhesive tape may include a first adhesive strip having an adhesive material applied to the first adhesive strip on a first side of the adhesive tape, a second adhesive strip having the adhesive material applied to the second adhesive strip on the first side of the adhesive tape, the second adhesive strip substantially parallel with the first adhesive strip and separated from the first adhesive strip by a distance, and a non-adhesive region between the first adhesive strip and the second adhesive strip wherein the non-adhesive region is substantially free of adhesive on the first side of the adhesive tape.

In accordance with these and other embodiments of the present disclosure, a method for making adhesive tape may include applying an adhesive material to the adhesive tape to form a first adhesive strip on a first side of the adhesive tape and applying the adhesive material to the adhesive tape to form a second adhesive strip on the first side of the adhesive tape substantially parallel with the first adhesive strip and separated from the first adhesive strip by a distance, such that a non-adhesive region is formed between the first adhesive strip and the second adhesive strip wherein the non-adhesive region is substantially free of adhesive on the first side of the adhesive tape.

In accordance with these and other embodiments of the present disclosure, a method for protecting tabs of an edge connector of a circuit board may include applying a first adhesive strip of an adhesive tape to a first side of the circuit board and proximate to the tabs and applying a second adhesive strip of the adhesive tape to a second side of the circuit board and proximate to the tabs, wherein the second adhesive strip is substantially parallel to and is separated from the first adhesive strip by a distance such that a non-adhesive region formed over the distance between the first adhesive strip and the second adhesive strip and substantially free of adhesive covers the tabs.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a plan view of one side of an example circuit board, in accordance with the present disclosure;

FIG. 2 illustrates a protective masking tape, in accordance with the present disclosure; and

FIG. 3 illustrates a side elevation view of a circuit board with protective masking tape applied to protect tabs of the circuit board, in accordance with the present disclosure.

### DETAILED DESCRIPTION

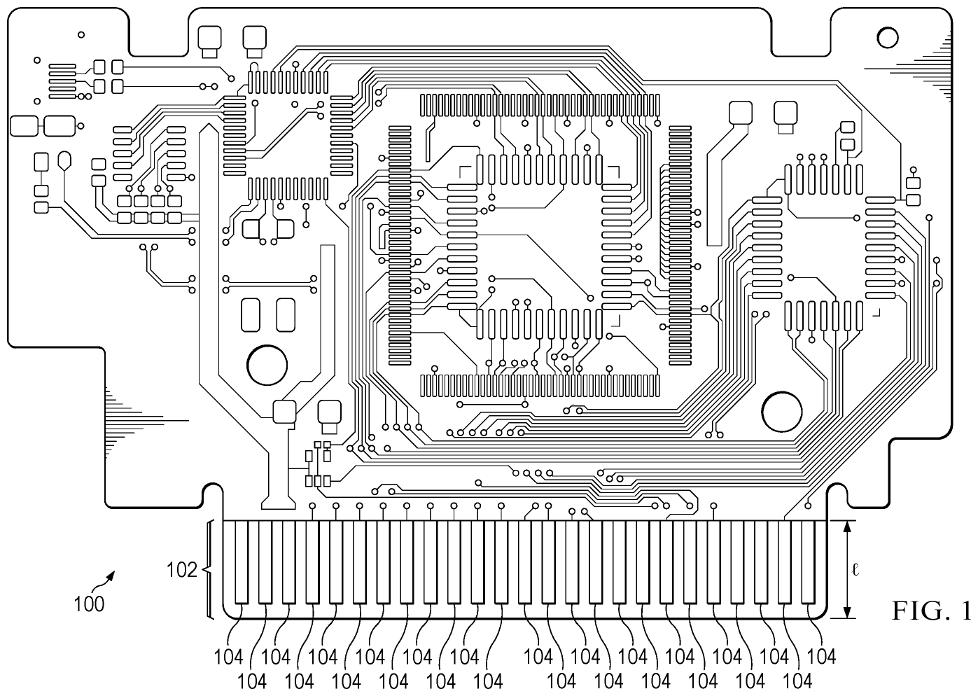

Preferred embodiments and their advantages are best understood by reference to FIGS. 1 through 3, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components or the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, information handling resources may broadly refer to any component system, device or apparatus of an information handling system, including without limitation processors, buses, memories, input-output devices and/or interfaces, storage resources, network interfaces, motherboards, integrated circuit packages; electro-mechanical devices (e.g., air movers), displays, and power supplies.

For the purposes of this disclosure, circuit boards may broadly refer to printed circuit boards (PCBs), printed wiring boards (PWBs), printed wiring assemblies (PWAs), etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a plan view of one side of example circuit board 100, in accordance with the present disclosure. As shown in FIG. 1, circuit board 100 may have formed at an edge thereof an edge connector 102 comprising a plurality of parallel electrically-conductive tabs 104. In addition to tabs 104 shown on the side of circuit board 100 depicted in FIG. 1, edge connector 102 may also include a plurality of parallel electrically-conductive tabs 104 on the opposite side of the side of circuit board 100 depicted in FIG. 1. Each tab 104 may be formed from an electrically conductive material (e.g., metal) and may be plated with gold or another metal. A tab 104 may further be electrically coupled to one or more traces, vias, and components of circuit board 100. As shown in FIG. 1, tabs 104 may have a length l.

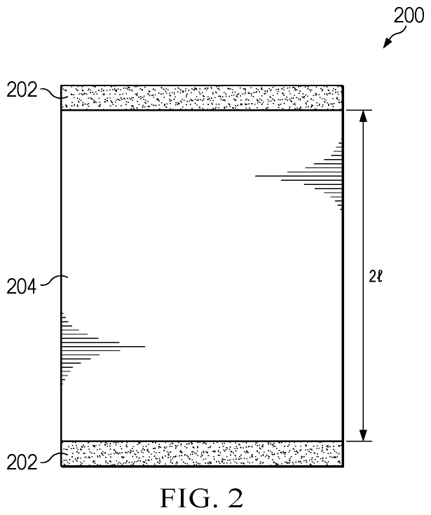

FIG. 2 illustrates a protective masking tape 200, in accordance with the present disclosure. Masking tape 200 may be made from a polyimide film (sometimes known as “Kapton”) or any other suitable material. As shown in FIG. 2, protective masking tape 200 may include substantially parallel adhesive strips 202 separated by a distance between each other at opposite edges of protective masking tape 200 with a non-adhesive region 204 between adhesive strips 202. The adhesive material used on adhesive strips 202 may include a silicone adhesive or any other suitable material. Non-adhesive region 204 may be free of adhesive on both sides of protective masking tape 200, while each adhesive strip 202 may include an adhesive material applied on one side of protective masking tape 200, such that protective masking tape 200 may adhere to a surface by applying one or both adhesive strips 202 to such surface on the side of protective masking tape 200 to which adhesive is applied to adhesive strips 202. Further as shown in FIG. 2, the distance between adhesive strips 202 (e.g., the width of non-adhesive region 204) may be at least two times the length l of tabs 104.

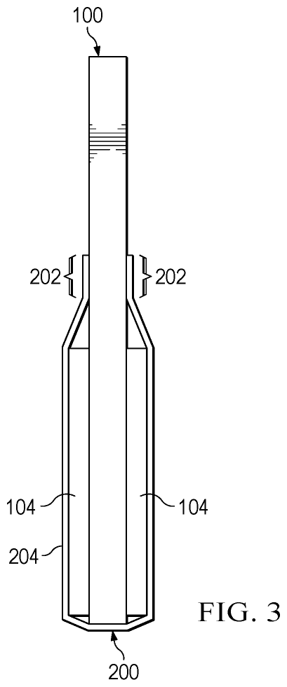

FIG. 3 illustrates a side elevation view of circuit board 100 with protective masking tape 200 applied to protect tabs 104 of circuit board 100, in accordance with the present disclosure. As shown in FIG. 3, in order to protect tabs 104 during an assembly process for circuit board 100, protective masking tape 200 may be applied by using the adhesive on a first adhesive strip 202 to adhere the first adhesive strip 202 to an area proximate to tabs 104 on a surface of a first side of circuit board 100, then wrap protective masking tape 200 around the edge of circuit board 100 at which connector 102 is formed and using the adhesive on a second adhesive strip 202 to adhere the second adhesive strip 202 to an area proximate to tabs 104 on a surface of a second side of circuit board 100. Once protective masking tape 200 is applied to circuit board 100 as described, protective masking tape 200 may provide a protective barrier around tabs 104 to protect tabs 104 from contamination during the assembly process of circuit board 100, while reducing (vis-à-vis traditional approaches) or eliminating contamination of tabs 104 with adhesive residue once protective masking tape 200 is removed after the assembly process.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An adhesive tape comprising:
a first adhesive strip having an adhesive material applied to the first adhesive strip on a first side of the adhesive tape;
a second adhesive strip having the adhesive material applied to the second adhesive strip on the first side of the adhesive tape, the second adhesive strip substantially parallel with the first adhesive strip and separated from the first adhesive strip by a distance; and
a non-adhesive region between the first adhesive strip and the second adhesive strip wherein the non-adhesive region is substantially free of adhesive on the first side of the adhesive tape.

2. The adhesive tape of claim 1, wherein the adhesive tape is made of polyimide film.

3. The adhesive tape of claim 1, wherein the distance is at least two times the length of substantially parallel tabs formed on an edge of a circuit board to which the adhesive tape is to be applied.

4. A method for making adhesive tape comprising:
applying an adhesive material to the adhesive tape to form a first adhesive strip on a first side of the adhesive tape; and
applying the adhesive material to the adhesive tape to form a second adhesive strip on the first side of the adhesive tape substantially parallel with the first adhesive strip and separated from the first adhesive strip by a distance;
such that a non-adhesive region is formed between the first adhesive strip and the second adhesive strip wherein the non-adhesive region is substantially free of adhesive on the first side of the adhesive tape.

5. The method of claim 4, wherein the adhesive tape is made of polyimide film.

6. The method of claim 4, wherein the distance is at least two times the length of substantially parallel tabs formed on an edge of a circuit board to which the adhesive tape is to be applied.

7. A method for protecting tabs of an edge connector of a circuit board, the method comprising:
applying a first adhesive strip of an adhesive tape to a first side of the circuit board and proximate to the tabs; and
applying a second adhesive strip of the adhesive tape to a second side of the circuit board and proximate to the tabs, wherein the second adhesive strip is substantially parallel to and is separated from the first adhesive strip by a distance such that a non-adhesive region formed over the distance between the first adhesive strip and the second adhesive strip and substantially free of adhesive covers the tabs.

8. The method of claim 7, wherein the distance is at least two times the length of the tabs.
